(19) United States
(12) Patent Application Publication
(10) Pub. No.: US 2013/0119503 A1
(43) Pub. Date: May 16, 2013

(54) DETECTION DEVICE FOR TWO DIFFERENT COLOURS WITH IMPROVED OPERATING CONDITIONS

(71) Applicant: Societe Francaise de Detecteurs Infrarouges - Sofradir, Chatenay Malabry (FR)

(72) Inventors: Fabien CHABUEL, Echirolles (FR); Laurent RUBALDO, Fontaine (FR)

(73) Assignee: SOCIETE FRANCAISE DE DETECTEURS INFRAROUGES- SOFRADIR, Chatenay Malabry (FR)

(21) Appl. No.: 13/678,015

(22) Filed: Nov. 15, 2012

(30) Foreign Application Priority Data
Nov. 15, 2011 (FR) 1103469

(51) Int. Cl. H01L 27/146

(52) U.S. Cl. CPC H01L 27/14643
USPC 257/443

(57) ABSTRACT

The substrate includes successively a first semiconductor layer having a first bandgap energy, a semiconductor buffer layer, a second semiconductor layer having a first bandgap energy different from the first bandgap energy. Two photodetectors sensitive to two different colors are formed respectively on the first and second semiconductor layers. A first biasing pad electrically connects the first semiconductor layer to a first biasing circuit. A second biasing pad electrically connects the second semiconductor layer to a second biasing circuit. The first biasing pad is devoid of electrical contact with the second semiconductor layer.

### BACKGROUND OF THE INVENTION

The invention relates to a detection device comprising a first photodetector responsive to a first color and a second photodetector responsive to a second color, the two photodetectors being operable simultaneously.

### STATE OF THE ART

In the field of detecting devices, there is commonly a photodetector associated with a readout circuit. The photodetector delivers a signal representative of the observed scene and the readout circuit processes this signal.

The transformation of the electromagnetic signal into a representative electrical signal is obtained by means of biasing the photodetector in a particular voltage range. Biasing the photodetector is obtained by means of the potential substrate applied on a first terminal of the photodetector. Biasing the photodetector is also obtained by means of a reference potential applied on a second terminal of the photodetector, for example by a readout device of the capacitive transimpedance amplifier type.

To get more and more information about the observed scene, the photodetector is associated with an additional photodetector sensitive to another color. The additional photodetector is also biased by means of the substrate and by means of its second terminal connected to a second readout circuit. In this way, the same scene can provide two different information depending on whether the information comes from the first photodetector or from the second photodetector, if the scene emits two different signals in two different colors. Such a photodetector is described in document U.S. Pat. No. 6,034,407.

Although the two photodetectors are configured to sense different wavelengths, we observe that this configuration of the device is particularly sensitive to illumination crosstalk phenomena. We note that the information contained in the wavelength associated with one of the two photodetectors can be found partly in the signal stored in the readout circuit associated with the other photodetector. Thus mixing of the signals limits the usefulness of this architecture.

### OBJECT OF THE INVENTION

The object of the invention is to provide a detection device that is less sensitive to mixing of the information contained in the two colors associated with two photodetectors.

This object is at least partly reached by a device comprising:
A substrate successively comprising:
   a first semiconductor layer having a first bandgap energy,
   a semiconductor buffer layer configured so as to block a charge carrier current between the first semiconductor layer and a second semiconductor layer,
   the second semiconductor layer having a second bandgap energy different from the first bandgap energy,
a first photodiode sensitive to a first colour and having a first electrode formed by means of the first semiconductor layer,
a second photodiode sensitive to a second colour and having a first electrode formed by means of the second semiconductor layer and separated from the first photodiode by the buffer layer,
a readout circuit electrically coupled to the first and second photodiode
a first biasing pad electrically connected to the first semiconductor layer and devoid of electrical connexion with the second semiconductor layer,
a first contact connected to a second electrode of the first photodiode,
a second biasing pad electrically connected to the second semiconductor layer and devoid of electrical connexion with the first semiconductor layer,
a second contact connected to a second electrode of the second photodiode,
a first biasing circuit configured to apply a first potential difference between the first biasing pad and the first contact,
a second biasing circuit configured to apply a second potential difference between the second biasing pad and the second contact.

### BRIEF DESCRIPTION OF THE DRAWINGS

Other advantages and features will become more clearly apparent from the following description of particular embodiments of the invention given for non-restrictive example purposes only and represented in the appended drawings, in which:

FIG. 1 schematically represents a detection device provided with two photodetectors,

FIG. 2 schematically represents a detection device having a plurality of pairs of photodetectors associated with a second polarization pad in different configurations, in top view,

FIG. 3 schematically represents the electric representation of the two photodiodes in the detection device.

### DESCRIPTION OF A PREFERRED EMBODIMENT OF THE INVENTION

As illustrated in FIG. 1, the detection device comprises a first photodetector 1 sensitive to a first color and a second photodetector 2 sensitive a second color different from the first color. The first 1 and 2 photodetectors are formed on a substrate 3. The substrate 3 comprises successively a support 4, a first semiconductor layer 5 having a first band gap energy, a semiconductor buffer layer 6 and a second semiconductor layer 7 having a second band gap energy different from the first band gap energy.

Preferably, the first band gap energy is larger than the second band gap energy so as to enhance the efficiency in collecting the incident radiation passing through the first semiconductor layer 5 for reaching the second semiconductor layer 7.

Even more preferably, the support is transparent to the two colors associated respectively with the first photodetector 1 and the second photodetector 2 in order to promote collection of light through the support. The support is, for example, made of a semiconductor material having a bandgap energy greater than the bandgap energy of the first semiconductor layer 5 and greater than the bandgap energy of the second semiconductor layer 7.

In a particular embodiment which can be combined with the preceding embodiments, the buffer layer 6 is also transparent to colors sensed by the first photodetector 1 and by the second photodetector 2. The buffer layer 6 is, for example, made of a semiconductor material having a bandgap energy greater than the bandgap energy of the first semiconductor layer 5 and greater than the bandgap energy of the second semiconductor layer 7.

The first photodetector 1 is partly formed by the first semiconductor layer 5 and the second photodetector 2 is partly formed by the second semiconductor layer 7. The first photodiode 1 has a first electrode formed by means of the first semiconductor layer 5. The second photodiode 2 has a first electrode formed by means of the second semiconductor layer 7. The first 1 and second 2 photodetectors are laterally shifted, that is to say that the collection zone of the first photodetector 1 is separated from the collection zone of the second photodetector 2, in top view and in cross-section view.

In a particular embodiment, the first photodetector 1 and the second photodetector 2 are both photodiodes. In this case a first diode is formed in the first semiconductor layer 5 and a second diode is formed in the second semiconductor layer 7. The two diodes are shifted laterally from each other so as to form a semi-planar architecture (in a plane parallel to the interface between the layer 5 and the layer 6).

The two photodetectors are connected to a readout circuit 8 receiving the signals from the two photodetectors 1, 2 in order to integrate, to store and/or analyze said signals for then send them to a processing circuit.

In a particular embodiment, the detection device comprises a detection array which is formed by a plurality of first photodetectors 1 and a plurality of second photodetectors 2, on the substrate 3. Advantageously, there are as many first photodetectors as second photodetectors 2. Even more advantageously, a first photodetector 1 is disposed in close proximity to a second photodetector 2 and the two photodetectors are arranged in the same manner with the same repetition pitch or with the same repetitions pitches between two first photodetectors and two second photodetectors in the direction (Ox) or in the directions (Ox, Oy) of organization of photodetectors in the detection array.

In this case, the detection array is associated with a readout circuit 8 comprising a plurality of readout devices 8a, 8b which are connected to the photodetectors. A photodetector is linked to a readout device 8a, 8b so as to receive the signal emitted from the photodetector. The readout device 8a is coupled to the first photodetector 1 so as to receive the emitted signal. The readout device 8b is coupled to the second photodetector 2 so as receive the emitted signal.

The detection device comprises a first biasing circuit configured for biasing the first photodetector 1. The first biasing circuit is configured to apply a first potential difference between the terminals of the first photodetector 1. The first biasing circuit is configured to apply a first potential difference between the first biasing pad 9 and the first contact 19. The value of the first potential difference is configured so as to obtain a first condition for transforming the received optical signal into an electric signal, for example a first coefficient of conversion of the received light flux into a current generated by the diode. For example, when the photodetectors are photodiodes, biasing is configured to reverse bias the photodiode.

The detection device comprises a second biasing circuit configured for biasing the second photodetector 2. The second biasing circuit is configured to apply a second potential difference between the terminals of the second photodetector 2. The second biasing circuit is configured to apply a second potential difference between the second biasing pad 9 and the second contact 19. Preferably, the second potential difference is different from the first potential difference. The value of the second potential difference is configured so as to obtain a second condition for transforming the received optical signal into an electrical signal, for example a second coefficient of conversion which can be different from the first coefficient of conversion.

In a particular embodiment, the first and second biasing conditions are different, so as to operate the first photodetector 1 or the second photodetector 2 in a different operating mode from the other photodetector. For example, one of the two photodetectors is subjected to a biasing greater than the other photodetector, so as to form an avalanche photodetector, the other photodetector having more linear operation between the received optical signal and the electrical signal issued.

Biasing the two photodetectors is carried out by applying two different potentials on the both pairs of terminals. A first terminal of the photodetector is formed by the substrate and a second terminal is formed by an electrical contact 18, 19 disposed on the substrate. The electrical contact 18, 19 is facing the photodetector. The first contact 19 is connected to a second electrode of the first photodiode 1 and the second contact 18 is connected to a second electrode of the second photodiode 2.

The first terminal of the photodetector is formed by the substrate 3 and more particularly by the semiconductor layer associated with the photodetector. A substrate potential V_{SUB} is applied to the first terminal by a voltage source via the associated semiconductor layer and a biasing pad.

The second terminal is electrically linked to the readout circuit 8, which can be used to impose a reference potential V_{REF}. The reference potential V_{REF} can also be applied by another circuit or a combination of the readout circuit 8 and another circuit. A reverse configuration is also possible

The biasing circuit of the first photodetector 1 comprises a first voltage source 14 and a first readout device 8b or another circuit (not shown). The biasing circuit of the second photodetector 2 comprises a second voltage source 15 and a second readout device 8a or another circuit (not shown).

A first substrate potential V_{SUB1} is applied in the substrate 3 by the first voltage source 14 via the first semiconductor layer 5 and a first biasing pad 9. A second substrate potential V_{SUB2} is applied in the substrate 3 by the second voltage source 15 via the second semiconductor layer 7 and a second biasing pad 10.

In a particular embodiment, the first biasing pad 9 is electrically coupled to the first biasing circuit 14 configured so as to provide a first substrate potential V_{SUB1}. The second biasing pad 10 is electrically coupled to the second biasing circuit 15 configured so as to provide a second substrate potential V_{SUB2} different from the first substrate potential V_{SUB1}. The readout circuit (8, 8a, 8b) forms a part of the first and second biasing circuits and is configured to provide a same reference voltage V_{REF} on the first electrodes of the first and second photodiodes 1, 2 so that the first potential difference is different from the second potential difference.

The buffer layer 6 is a layer that blocks the passage of a current of charge carriers or severely limits the passage of the charge carriers. The buffer layer 6 can be subjected to a potential difference without allowing the passage of the charge carriers. The buffer layer 6 is preferably an intrinsic semiconductor layer (not intentionally doped) having a bandgap energy greater than the bandgap energy of the first and second semiconductor layers.

The first and second biasing pads 9 and 10 are made preferably with a low-resistance material such as a metal material to facilitate evacuation of the charges.

The first biasing pad 9 electrically connects the first biasing circuit to the first semiconductor layer 5. The first biasing pad 9 is electrically connected to the first semiconductor layer 5 and has no electric connection with the second semiconductor layer 7 which prevents a transfer of charges between the two photodetectors and/or between the two readout circuits 8b, 8a. The first biasing pad 9 penetrates into the substrate 3 so as to electrically connect the first semiconductor layer 5.

In a particular embodiment which can be combined with the preceding embodiments, the substrate 3 preferably comprises a first blind hole with a bottom and at least one sidewall. The first hole penetrates into the second semiconductor layer 7 and the buffer layer 6 so as to stop at the surface or inside of the first semiconductor layer 5 or inside the support 4. Preferably, the first blind hole stops inside the first semiconductor layer 5 in order to obtain a reduced contact resistance, the bottom of the first hole is formed in the first semiconductor layer 5. The substrate 3 comprises sidewalls defining the first hole. The sidewalls are at least partially covered by an electrically insulating material 11 so as to prevent short-circuit with the second semiconductor layer 7.

The second biasing pad 10 electrically connects the second biasing circuit to the second semiconductor layer 7. The second biasing pad 10 is electrically connected to the second semiconductor layer and is devoid of electrical contact with the first semiconductor layer 5. The second biasing pad 10 may be disposed on the surface of the substrate 3 or it can penetrate into the substrate 3 comprising, for example, a second blind hole with a bottom and at least one sidewall. The second biasing pad 10 is free of electrically conductive interface with the first semiconductor layer 5 and with the buffer layer 6. The second blind hole can stop at the surface or inside of the second semiconductor layer 7. Preferably, the second blind hole stops inside the second semiconductor layer 7 so as to obtain a reduced contact resistance. The sidewalls of the second hole are preferably devoid of electrically insulating material so as to obtain an important electrical contact surface between the second semiconductor layer 7 and the second biasing pad 10 when the second blind hole stops in the second semiconductor layer 7.

It was discovered that this particular architecture with two separate biasing pads associated respectively with the first photodetector 1 and the second photodetector 2 enables a more robust detection device to be obtained in the event of strong illumination with a strong reduction of the mixture of the two optical signals sent.

In the prior art, one metal pad electrically connects the two semiconductor layers with a common potential substrate. In this configuration, the inventors have observed that when one of the two photodetectors is subjected to an important illumination, biasing of the semiconductor layer is changed and some of the electric charges generated by the photodetector are sent to the other semiconductor layer having a different potential. In this way, one of the two readout devices gets more electric charges and the other readout device receives less electrical charge. The analysis of the observed scene is distorted.

By means of an architecture devoid of common electrical contact between the first semiconductor layer 5 and the second semiconductor 7, it is possible to reduce or even to overcome this exchange of electrical charges. The first and second photodiodes do not share electrical contact. The electrical signals provided by the two photodiodes are dissociated.

For example, document U.S. Pat. No. 0,747,962 discloses a structure with two photodiodes having a common anode. In this configuration, the two photodiodes mix the electrical signals when they operate simultaneously.

In a preferred embodiment which can be combined with previous embodiments, in a detection array, a second biasing pad 10 is associated with each second photodetector 2 to ensure the homogeneity of the biasing conditions in the entire detection array. There are as many second photodetectors 2 as second biasing pads 10. The substrate is used to apply the voltage V_{SUB2} at the first terminal and the readout circuit imposes the voltage V_{REF}.

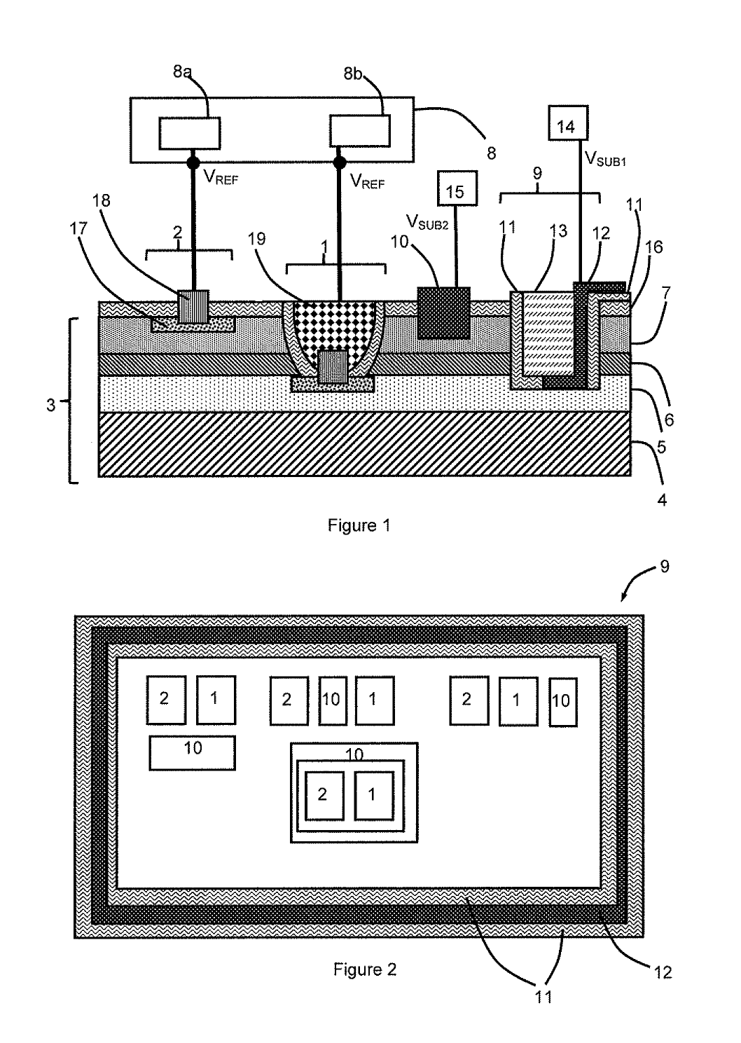

As shown in FIG. 2, the second biasing pad 10 may have any shape, eg square or circular. The second biasing pad 10 may be placed on one side of the two photodetectors, or between the two photodetectors. The second biasing pad 10 can be aligned with the two photodetectors and separated from the first photodetector 1 by the second photodetector 2 or vice versa. In another case, the second biasing pad 10 is not aligned with the two photodetectors and the second biasing pad 10 is facing one of the two photodetectors, or facing the two photodetectors in a direction substantially perpendicular to the axis passing by the two photodetectors. In a particular embodiment, the second biasing pad 10 forms a closed trench around the two photodetectors so as to facilitate dissipation of the electrical charges. Seen from above or below, the closed trench is in the form of a ring whose center is filled by the two photodetectors.

Even more preferably, the first biasing pad 9 is common to several first photodetectors 1. As the first biasing pad 9 is formed through the second layer 7 and the buffer layer 6, the surface area occupied by the first hole is important. Sharing the first biasing pad 9 with several first photodetectors 1 allows to keep a large integration density. There is therefore less first biasing pads 9 than first photodetectors 1. Advantageously, the first hole associated with the first biasing pad is in the form of a closed trench defining a closed surface, a first region in the substrate which contains a plurality of first photodetectors 1. Seen from above or below, the closed trench is in the form of a ring whose center is filled by a plurality of first photodetectors 1, by a plurality of second photodetectors 2 and by several second biasing pads 10. The first region of the substrate is defined by a first sidewall which is common with the sidewall of the trench. In other words, the first blind hole defines a closed trench with a ring-shape defining a first region of the first semiconductor layer 5 and a first region of the second semiconductor layer 7. A plurality of first photodetectors 1 and a plurality of second photodetectors 2 are arranged in said first region. Preferably, a plurality of second biasing pads 10 are arranged in the first region.

In a particularly advantageous embodiment, the hole of the first biasing pad 9 is a closed trench forming a ring around the detection array, in the substrate 3. All the first photodetectors 1 of the array are within the area bounded by the trench of the first biasing pad 9. There is only one first biasing pad 9 for the entire detection array. Advantageously, the first biasing pad 9 forms a ring around the detection array in order to homogenize the biasing conditions.

In a particular embodiment which may be combined with the previous embodiments, the first biasing circuit is configured to apply a greater bias on the first photodetector 1 than the bias on the second photodetector 2. Even more preferably, the first biasing circuit is configured to operate the first photodetector 1 as an avalanche photodetector. In other words, the first biasing circuit 14 is configured to bias the first photodiode 1 in a first voltage range wherein the first photodiode is an avalanche photodiode and the second biasing circuit 15 is configured to bias the second photodiode 2 in a second voltage range wherein the first photodiode has a linear response between an optical signal and an electrical signal.

It is important to form a first biasing pad 9 which is electrically insulated from the second semiconductor layer 7 and whose structure is robust to the fluctuations of the manufacturing process. This electrical insulation between the two layers is particularly useful when significant differences in biasing are applied between the two types of photodetectors and when short circuit can damage or destroy one of the two photodetectors.

The first hole of the first biasing pad 9 comprises a bottom and at least one sidewall. The bottom of the first blind hole is formed by the first semiconductor layer 5. Advantageously, the bottom of the first hole is disposed within the first semiconductor layer 5 and not on the surface of this layer in order to have a better robustness of the production process vis-à-vis the fluctuation in the production process. The first biasing pad 9 penetrates into the substrate 3 through the second semiconductor layer 7 and the buffer layer 6.

The sidewall or the sidewalls of the first hole are partially covered by an electrically insulating material 11 so that the second semiconductor layer 7 and the buffer layer 6 have an interface with the electrically insulating material 11. Advantageously, all the sidewalls of the first hole are completely covered by the electrically insulating material 11 in order to have a robust device and to limit the probability of having short circuit with the layers 6 and 7. When the hole penetrates into the first semiconductor layer 5, it is advantageous to leave the electrically insulating material 11 on the sidewall of the hole so that there is an interface between the layer 11 and the first semiconductor layer 5. In this way, the risk of short-circuit by the sidewalls at the interface between the buffer layer 6 and the first semiconductor layer 5 are reduced.

The bottom of the first hole is partially covered by the electrically insulating material 11 and the coated portion is located in the extension of the sidewalls. In cross-section, the electrically insulating layer 11 is L-shaped in FIG. 1. An electrically conductive film 12 is deposited in the first blind hole so as to connect the first semiconductor layer 5 and to realize an electrical connection between the first biasing circuit and the semiconductor layer 5. The electrically conductive film 12 opens out the first hole and extends on the surface of the substrate 3 so as to increase connection area with a voltage source. The contact area between an electrically conductive film 12 and the semiconductor layer 5 is smaller than the area of the bottom of the hole, in order to maintain a robust process. In an even more preferential way, the contact area between the film 12 and the layer 5 is smaller than the bottom of the first hole so as to form a guard zone covered by the electrically insulating film 11 in the bottom of the first hole.

Preferably, the electrically conductive film 12 partially overlaps the sidewalls of the first hole so as to reduce the contact area between the electrically insulating film 11 and the electrically conductive film 12. This limitation of the overlap area of the film 12 over the film 11 allows to reduce the probability of short-circuit through the film 11 and allows to make the production process more robust if the film 11 fails. The electrically conductive film 12 preferably extends beyond the trench so as to cover the upper face of the substrate out of the first region which allows easy and secure electrical contact to be obtained.

When the first biasing pad 9 is associated with a closed trench forming a ring around a group of photodetectors, there is a first side wall adjacent to the photodetectors, the inner wall and a second sidewall opposite in the substrate 3, the outer wall. The two sidewalls are linked by the bottom of the trench.

In other words, the substrate 3 comprises a first sidewall defining the first region and a second sidewall opposite the first sidewall.

An electrically conductive film 12 is formed in the bottom of the hole and extends along the outer wall opposite the inner wall. In a cross-section plane parallel to the interface between the buffer layer 6 and the first semiconductor layer 5, the electrically insulating film 11 covering the outer wall is separated from the electrically insulating film 11 covering the inner wall by means of the electrically conductive film 12. The electrically conductive film 12 is separated from the second photodetector 2 by the electrically insulating film 11 and by an additional electrically insulating material 13. The electrically insulating material 13 may be a free zone or a gas. The electrically insulating material 13 may also be a material deposited in the first hole on the electrically insulating material 11 and on the electrically conductive material 12. Materials 11 and 13 can have identical chemical compositions.

In other words, the trench has successively in a cross-section plane parallel to the interface between the buffer layer 6 and the first semiconductor layer 5, from the outer wall towards the inner wall, an electrically insulating film 11, the electrically conductive film 12, the electrically insulating material 13 deposited on the electrically conductive film 12 and the electrically insulating film 11.

In a preferred alternative embodiment that may be combined with the previous embodiment and illustrated in FIG. 1, the connection area between the first semiconductor layer 5 and the electrically conductive film 12, in the bottom of the first hole, is shifted to the outer wall so as to have a guard zone covered by the electrically insulating film 11.

In this case, in a top view, in the bottom of the first hole, there is a first ring made of the electrically insulating material 11 which is surrounded by a second ring made of the electrically conductive material 12. Thus, even if a problem of manufacturing occurs with the electrically insulating material 11 on the sidewalls, the part of the second semiconductor layer 7 delimited by the closed trench of the first biasing pad 9 is not in electrical contact with the film 12. The two rings surround the first region of the substrate 3 comprising advantageously a plurality of first photodetectors and a plurality of second photodetectors. In other words, the electrically insulating film 11 defines a first ring in the bottom of the blind hole so as to surround the first region of the first semiconductor layer 5. The electrically conductive film 12 defines a second ring surrounding the first ring in the bottom of the blind hole.

This embodiment is particularly advantageous when the trench of the first biasing pad 9 is formed around the array. In this case, there is no risk of short circuit between the two semiconductor layers in the array.

In this embodiment, it may even be possible to eliminate the electrically insulating layer 11. The part of the second semiconductor layer 7 which is in electrical contact with the first layer 5 does not connect a second photodetector 2 and is not connected to a readout circuit 8.

The electrically conductive film 12 preferably opens out of the first hole so as to form a contact for the first biasing circuit. The electrically conductive film 12 is separated from the surface of the substrate by an electrically insulating layer 16 to prevent a short circuit with the upper side of the second semiconductor layer 7.

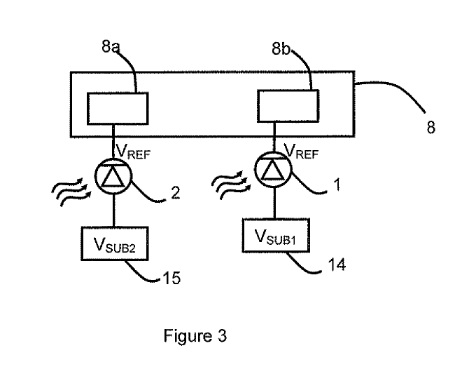

In the particular embodiment illustrated in FIGS. 1 and 3, the photodetectors 1 and 2 are both photodiodes. The first semiconductor layer 5 is of a first type of conductivity and a doped region 17 of a second type of conductivity exists in the layer 5 so as to form the diode of the first photodetector 1. The same is true for forming the diode of the second photodetector 2 in the second semiconductor layer 7. The two photodiodes have the same Anode-Cathode orientation observed in comparison with the stack of the substrate 3 or with the propagation of the incidental flux. Advantageously, the first semiconductor layer 5 and the second semiconductor 7 are of the same type of conductivity in order to operate simultaneously and to analyze the same observed scene by means of a control circuit setting the bias and actuating the readout circuit. Preferably, the two photodetectors comprise a contact 18, 19 which is metallic or metal-based so as to reduce the access resistance of the device. The contact 18, 19 is electrically connected to the doped region 17 so as to partially define the bias of the photodiode. It is also possible to have first and second semiconductor layers with opposite type of conductivity, but this embodiment is more sensitive to insulating properties of the buffer layer 6.

As illustrated in FIG. 3, the two photodiodes are electrically dissociated so as to present dissociation in biasing parameters and in electrical signal provided by the photodiodes.

In a particular embodiment, the support 4 can be eliminated or it may have a reduced thickness so as to minimize thermo-mechanical stresses.

The device can be realized with conventional techniques, for example by forming the substrate 3 with its different layers. The photodetectors are then formed. The trench of the first biasing pad 9 and the biasing pad 9 are formed. Photodetectors may be formed before or after the holes. It is still possible to form the holes during the forming process of the photodetectors. The first photodetector is formed by a hole penetrating down to the first semiconductor layer 5, and then by means of an electrical contact providing the signal. The insulating layer 11 may be deposited simultaneously in the contact hole 9 and the hole of the first photodetector.

Preferably, the various layers of the substrate are monocristalline so as to promote electrical performances of the detection device. Advantageously, the different semiconductor layers present matching of the lattice parameter so as to form a monolithic assembly with enhanced thermomecanical properties and with a good distribution of heat and cold. For example, the support can be made of CdZnTe and the other semiconductor layers are made of HgCdTe. Other materials can be chosen. Advantageously, the different semiconductor layers are formed by epitaxy, for example by Molecular Beam Epitaxy, By Liquid Phase Epitaxy.

1. Detection circuit comprising:
A substrate successively comprising:
a first semiconductor layer having a first bandgap energy,
a semiconductor buffer layer configured so as to block a charge carrier current between the first semiconductor layer and a second semiconductor layer,
the second semiconductor layer having a second bandgap energy different from the first bandgap energy,
a first photodiode sensitive to a first colour and having a first electrode formed by means of the first semiconductor layer,
a second photodiode sensitive to a second colour and having a first electrode formed by means of the second semiconductor layer and separated from the first photodiode by the buffer layer,
a readout circuit electrically coupled to the first and second photodiode,
a first biasing pad electrically connected to the first semiconductor layer and devoid of electrical connexion with the second semiconductor layer,
a first contact connected to a second electrode of the first photodiode,
a second biasing pad electrically connected to the second semiconductor layer and devoid of electrical connexion with the first semiconductor layer,
a second contact connected to a second electrode of the second photodiode,
a first biasing circuit configured to apply a first potential difference between the first biasing pad and the first contact,
a second biasing circuit configured to apply a second potential difference between the second biasing pad and the second contact.

2. Device according to claim 1, wherein the substrate comprises a blind hole having a bottom formed in the first semiconductor layer wherein an electrically conductive film realizes an electrical connexion between the first biasing circuit and the bottom of the blind hole so that the first biasing pad penetrates into the substrate through the second semiconductor layer and the buffer layer.

3. Device according to claim 2, wherein the blind hole defines a closed trench in the form of a ring, the ring defining a first region in the first semiconductor layer with a plurality of first photodiodes and a first region in the second semiconductor layer with a plurality of second photodiodes.

4. Device according to claim 3, comprising a plurality of second biasing pads disposed in the first region in the second semiconductor layer.

5. Device according to claim 3, wherein the closed trench has a first sidewall defining the first region in the first semiconductor layer and a second sidewall opposite to the first sidewall, the first biasing pad comprise successively, in a cross-section plane parallel to an interface between the first semiconductor layer and the semiconductor buffer layer, from the second sidewall to the first sidewall:
an electrically insulating film,
the electrically conductive film,
an electrically insulating material deposited on the electrically conductive film and on the electrically insulating film.

6. Device according to claim 5, wherein the electrically insulating film defines a first ring in the bottom of the blind hole so as to surround the first region of the first semiconductor layer and in that the electrically conductive film defines a second ring surrounding the first ring in the bottom of the blind hole.

7. Device according to claim 1, wherein the first biasing pad is electrically coupled to the first biasing circuit configured so as to provide a first substrate potential, the second biasing pad is electrically coupled to the second biasing circuit configured so as to provide a second substrate potential different from the first substrate potential and in that the readout circuit forms a part of the first and second biasing circuits and is configured to provide a same reference voltage on the first electrodes of the first and second photodiodes so that the first potential difference is different from the second potential difference.

8. Device according to claim 7, wherein the first biasing circuit is configured to bias the first photodiode in a first voltage range wherein the first photodiode is an avalanche photodiode and in that the second biasing circuit is configured to bias the second photodiode in a second voltage range wherein the first photodiode has a linear response between an optical signal and an electrical signal.
